(19) United States
(12) Patent Application Publication
(10) Pub. No.: US 2012/0241813 A1
(43) Pub. Date: Sep. 27, 2012

(54) POWER SEMICONDUCTOR DEVICE

(75) Inventor: Ryohei GEJO, Hyogo-ken (JP)

(73) Assignee: Kabushiki Kaisha Toshiba, Tokyo (JP)

(21) Appl. No.: 13/239,097

(22) Filed: Sep. 21, 2011

(30) Foreign Application Priority Data
Mar. 24, 2011 (JP) 2011-065314

(51) Int. Cl. H01L 29/739

(52) U.S. Cl. 257/139; 257/E29.198

(57) ABSTRACT

A power semiconductor device includes a first semiconductor layer of a first conduction type, a second semiconductor layer of the first conduction type, a third semiconductor layer of a second conduction type, a fourth semiconductor layer of the first conduction type, a gate insulating film, a gate electrode, an interlayer insulating film, a fifth semiconductor layer of the second conduction type, a sixth semiconductor layer of the second conduction type, an insulative current narrowing body, a first electrode, and a second electrode. The sixth semiconductor layer of the second conduction type contains a second conduction type impurity in a concentration higher than a second conduction type impurity concentration of the fifth semiconductor layer. The insulative current narrowing body is provided in the fifth semiconductor layer. The insulative current narrowing body has a surface parallel to the surface of the fifth semiconductor layer and a space provided in the surface.

### CROSS-REFERENCE TO RELATED APPLICATION

This application is based upon and claims the benefit of priority from the prior Japanese Patent Application No. 2011-065314, filed on Mar. 24, 2011; the entire contents of which are incorporated herein by reference.

### FIELD

Embodiments described herein relate generally to a power semiconductor device used in a power device.

### BACKGROUND

Power semiconductor devices such as IGBTs (Insulated Gate Bipolar Transistors), IEGTs (Injection Enhanced Gate Transistors), and the like (hereinafter, “IGBTs etc.”) used for switching elements in power devices such as inverters are required to reduce the power consumption in the ON state and reduce the turn-off power loss. The turn-off power loss is the power consumed when carries stored in a base layer are released at the time of turn-off. To reduce the turn-off power loss, it is effective to reduce the amount of carries injected into the base layer. To reduce the amount of carriers injected into the base layer, it is effective to reduce the concentration of the p-type impurity of a p⁺-type collector layer. However, reducing the p-type impurity concentration of the p⁺-type collector layer increases the resistance (or the ON voltage) of the collector layer and increases the power consumption in the ON state. Therefore, there is a trade-off relationship between reducing the power consumption in the ON state and reducing the turn-off power loss. IGBTs etc. in which carriers are injected into the base layer at low level and the ON resistance (the resistance of the collector layer) is low are desired.

### BRIEF DESCRIPTION OF THE DRAWINGS

FIG. 1 is a cross-sectional view of a main part of a power semiconductor device according to the first embodiment; and

FIG. 2 is a cross-sectional view of a main part of a power semiconductor device according to the second embodiment.

### DETAILED DESCRIPTION

A power semiconductor device includes a first semiconductor layer of a first conduction type, a second semiconductor layer of the first conduction type, a third semiconductor layer of a second conduction type, a fourth semiconductor layer of the first conduction type, a gate insulating film, a gate electrode, an interlayer insulating film, a fifth semiconductor layer of the second conduction type, a sixth semiconductor layer of the second conduction type, an insulative current narrowing body, a first electrode, and a second electrode. The second semiconductor layer of the first conduction type is provided on the first semiconductor layer and contains a first conduction type impurity in a concentration lower than a first conduction type impurity concentration of the first semiconductor layer. The third semiconductor layer of the second conduction type is formed on a surface of the second semiconductor layer on a side opposite to the first semiconductor layer. The fourth semiconductor layer of the first conduction type is formed on a surface of the third semiconductor layer on a side opposite to the first semiconductor layer and contains a first conduction type impurity in a concentration higher than a first conduction type impurity concentration of the second semiconductor layer. The gate insulating film is provided in contact with the second semiconductor layer, the third semiconductor layer, and the fourth semiconductor layer. The gate electrode is provided opposite the second semiconductor layer, the third semiconductor layer, and the fourth semiconductor layer via the gate insulating film. The interlayer insulating film is provided on the gate electrode and covers the gate electrode along with the gate insulating film. The fifth semiconductor layer of the second conduction type is provided on a surface of the first semiconductor layer on a side opposite to the second semiconductor layer. The sixth semiconductor layer of the second conduction type is provided on a surface of the fifth semiconductor layer on a side opposite to the first semiconductor layer and contains a second conduction type impurity in a concentration higher than a second conduction type impurity concentration of the fifth semiconductor layer. The insulative current narrowing body is provided in the fifth semiconductor layer. The insulative current narrowing body has a surface parallel to the surface of the fifth semiconductor layer and a space provided in the surface. The first electrode is electrically connected to the sixth semiconductor layer. The second electrode is electrically connected to the third semiconductor layer and the fourth semiconductor layer.

Hereinbelow, embodiments of the invention are described with reference to the drawings. The drawings used in the description of examples are schematic to facilitate the description. The shapes, dimensions, magnitude relationships, etc. of the components illustrated in the drawings are not necessarily the same as those in actual practice, and may be altered as appropriate to the extent that the effects of the invention are obtained. Silicon is used as an example of the semiconductor material. A description is given using an n-type and a p-type as a first conductive type and a second conductive type, respectively. In the case where an n⁻-type, an n-type, and an n⁺-type are used, it is assumed that there is a relationship of n⁻<n<n⁺ in the impurity concentrations thereof. This is also applied to a p⁻-type, a p-type, and a p⁺-type. In the case of, for example, referring to simply the concentration of a p-type impurity, it means the actual concentration of the p-type impurity contained in the semiconductor layer. In the case of, for example, referring to the net concentration of a p-type impurity, it means the concentration of the p-type impurity after compensation with the n-type impurity contained in the semiconductor layer. This is also applied to the concentration of an n-type impurity and the net concentration of a n-type impurity. Although the embodiments are described using an IGBT as an example of the power semiconductor device, the embodiments can be similarly applied also to semiconductor devices such as IEGTs and the like.

### First Embodiment

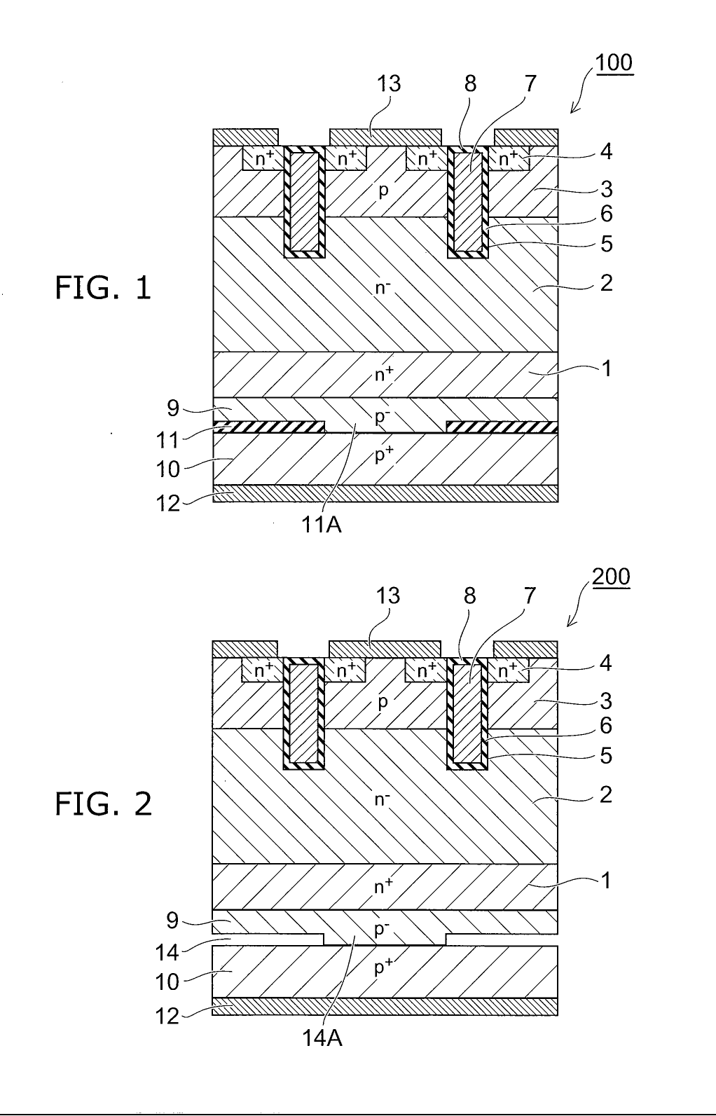

A first embodiment is described using FIG. 1. FIG. 1 is a cross-sectional view of a main part of an IGBT 100 that is a power semiconductor device according to the first embodiment. As shown in FIG. 1, the IGBT 100 according to the embodiment includes an n⁺-type (first conduction type) buffer layer (a first semiconductor layer) 1, an n⁻-type base layer (a second semiconductor layer) 2, a p-type (second conduction type) base layer (a third semiconductor layer) 3, an n⁺-type emitter layer (a fourth semiconductor layer) 4, a gate insulating film 6, a gate electrode 7, an interlayer insulating film 8, a p⁻-type first collector layer (a fifth semiconductor layer) 9, a p⁺-type second collector layer (a sixth semiconductor layer) 10, an insulative current narrowing body 11, a collector electrode (a first electrode) 12, and an emitter electrode (a second electrode) 13. A description is given using, as an example, the case where the n⁺-type buffer layer 1, the n⁻-type base layer 2, the p-type base layer 3, the n⁺-type emitter layer 4, the p⁻-type first collector layer, and the p⁺-type second collector layer are silicon.

The n⁺-type buffer layer 1 has, for example, a film thickness of approximately 10 μm and an n-type impurity concentration of 10¹⁵ to 10¹⁶ cm⁻³. The n⁻-type base layer 2 is provided on the n⁺-type buffer layer 1, and contains an n-type impurity in a concentration lower than the concentration of the n-type impurity in the n⁺-type buffer layer 1. For example, the n⁻-type base layer 2 has a film thickness of approximately 30 μm and an n-type impurity concentration of 10¹³ to 10¹⁴ cm⁻³. The p-type base layer 3 is formed on the surface of the n⁻-type base layer 2 on the side opposite to the n⁺-type buffer layer 1. The p-type base layer 3 has a film thickness of several micrometers and a p-type impurity concentration of 10¹⁶ to 10¹⁷ cm⁻³. The n⁺-type emitter layer 4 is formed on the surface of the p-type base layer on the side opposite to the n⁺-type buffer layer 1, and contains an n-type impurity in a concentration higher than the concentration of the n-type impurity in the n⁻-type base layer 2. The n⁺-type emitter layer 2 has a film thickness of approximately 1 μm and an n-type impurity concentration of 10¹⁹ to 10²⁰ cm⁻³.

A trench 5 is provided so as to be adjacent to the n⁺-type emitter layer 4, penetrate through the p-type base layer from the surface of the n⁺-type emitter layer 4, and reach the interior of the n⁻-type base layer 2. The gate insulating film 6 is provided so as to cover the entire inner surface (the entire side wall and the entire bottom surface) of the trench 5. The gate insulating film 6 may be, for example, a silicon oxide film formed by thermal oxidation, or a silicon oxide film formed by CVD or the like. In addition, in place of the silicon oxide film, a silicon nitride film and other dielectric materials may be used. The gate electrode 7 is provided in the trench 5 via the gate insulating film 6. The gate electrode 7 may be polysilicon doped to an n-type. The interlayer insulating film 8 is provided so as to cover the upper end of the gate electrode 7 and be connected to the gate insulating film 6. The interlayer insulating film 8 may be a silicon oxide film formed by thermal oxidation or CVD, similarly to the gate insulating film. The gate electrode 7 is insulated from the exterior of the trench by being surrounded by the gate insulating film 6 and the interlayer insulating film 8, except for the portion extracted through a not-shown opening provided in the interlayer insulating film 8 to a gate interconnection layer outside the trench 5.

The p⁻-type first collector layer 9 is provided on the surface of the n⁺-type buffer layer 1 on the side opposite to the n⁻-type base layer 2, and contains a p-type impurity in a concentration lower than the p-type impurity concentration of the p-type base layer 3. The p⁻-type first collector layer 9 has, for example, a film thickness of several micrometers and a p-type impurity concentration of 10¹⁵ to 10¹⁶ cm⁻³. Here, the net p-type impurity concentration of the p⁻-type first collector layer 9 is preferably set higher than the net n-type impurity concentration of the n⁺-type buffer layer 1. By setting the impurity concentration of the p⁻-type first collector layer in this way, holes are easily released from the p⁻-type first collector layer 9 to the n⁺-type buffer layer 1 at the time of turn-off, and the turn-off power loss is therefore reduced. The p⁺-type second collector layer 10 is provided on the surface of the p⁻-type first collector layer 9 on the side opposite to the n⁺-type buffer layer 1, and contains a p-type impurity in a concentration higher than the p-type impurity concentration of the p⁻-type first collector layer 9. The p⁺-type second collector layer 10 has a p-type impurity concentration of 10¹⁹ to 10²⁰ cm⁻³, for example.

The current narrowing body 11 is provided in the p⁻-type first collector layer 9, and has a surface parallel to the surface mentioned above of the p⁻-type first collector layer 9 and a space 11A provided in the surface. The current narrowing body 11 has sufficient insulating properties not to conduct a current in a direction perpendicular to the surface mentioned above of the p⁻-type first collector layer 9 (the stacking direction). The current narrowing body 11 may be, for example, an insulating film such as a silicon oxide film or a silicon nitride film. The space 11A of the current narrowing body 11 is filled with the p⁻-type first collector layer 9. The current narrowing body 11 is adjacent to the p⁺-type second collector layer 10 and away from the n⁺-type buffer layer 1 via the p⁻-type first collector layer 9.

In the case where the current narrowing body 11 is a silicon oxide film or a silicon nitride film, the current narrowing body can be formed by the following method, for example. A p⁻-type first collector layer is epitaxially grown on a p⁺-type second collector layer, and then a prescribed mask is used to implant oxygen ions or nitrogen ions into a portion adjacent to the p⁺-type second collector layer of the p⁻-type first collector layer through the surface of the p⁻-type first collector layer on the side opposite to the p⁺-type second collector layer, followed by heat treatment. Thereby, the current narrowing body 11 of a silicon oxide film or a silicon nitride film can be formed.

The collector electrode 12 is electrically connected to the p⁺-type second collector layer. The emitter electrode 13 is electrically connected to the n⁺-type emitter layer 4 and the p-type base layer 3. In FIG. 1, the emitter electrode 13 is not formed on the gate electrode 7 but formed only on the n⁺-type emitter layer 4 and the p-type base layer. However, this is only an example. As a matter of course, the emitter electrode 13 may has a structure extending over the gate electrode 7 via the interlayer insulating film 8. Furthermore, as a matter of course, also a configuration is possible in which the emitter electrode 13 is electrically connected to the p-type base layer 3 via a not-shown p⁺-type contact layer having a higher p-type impurity concentration than the p-type base layer.

Next, operations of the IGBT 100 according to the embodiment are described. When a voltage exceeding the threshold is applied to the gate electrode 7 with respect to the emitter electrode 13 in a state where a positive voltage is applied to the collector electrode 12 with respect to the emitter electrode 13, a channel layer caused by population inversion is formed in a portion adjacent to the gate insulating film 6 of the p-type base layer 3. Electrons are supplied from the emitter electrode 13 into the n⁻-type base layer 2 via the n⁺-type emitter layer 4 and the channel layer. Holes in an amount corresponding to the amount of the electrons are supplied from the collector electrode 12 to the n⁻-type base layer 2 via the p⁺-type second collector layer 10, the p⁻-type first collector layer 9, and the n⁺-type buffer layer 1. The electrons and the holes are stored in the n⁻-type base layer 2. Thereby, a conductivity change occurs to decrease the ON resistance rapidly, and the IGBT 100 is turned to the ON state.

When the voltage applied to the gate electrode 7 is made not more than the threshold, the channel layer mentioned above disappears. Thereby, the supply of electrons and holes into the n⁻-type base layer 2 is stopped, and the IGBT is switched from the ON state to the OFF state. At this time, since excessive electrons and holes stored in the n⁻-type base layer continue to flow toward the collector electrode and the emitter electrode, respectively, a current continues to flow for a certain period of time as a residual current. The residual current causes turn-off power loss. To reduce the turn-off power loss, it is effective to suppress the injection of holes from the p⁺-type second collector layer 10 into the n⁻-type base layer 2. As a method thereof, reducing the p-type impurity concentration of the p⁺-type second collector layer 12 may be possible. However, this leads to an increase in the collector resistance in the p⁺-type second collector layer and an increase in the ON resistance of the IGBT 100.

The IGBT 100 according to the embodiment includes the current narrowing body 11 that blocks the current into the p⁻-type first collector layer in the stacking direction, and the current narrowing body 11 has a surface parallel to the surface mentioned above of the p⁻-type first collector layer 9 and the space 11A provided in the surface. The space 11A is filled with the p⁻-type first collector layer 9. In the space 11A, the p⁻-type first collector layer 9 is electrically connected to the p⁺-type second collector layer 10. Thereby, the current flowing from the p⁺-type second collector layer 10 to the p⁻-type first collector layer is narrowed by the current narrowing body 11 and concentrated in the portion of the space 11A. As a consequence, in the portion of the space 11A of the current narrowing body 11 of the p⁻-type first collector layer 9, since the carrier densities of the electrons supplied from the emitter electrode 13 and the holes supplied from the collector electrode increase, the carrier lifetime is shortened to promote recombination of electrons and holes. The recombination of electrons and holes reduces the amount of holes supplied from the p⁺-type second collector layer 10 to the n⁻-type base layer. Therefore, in the IGBT 100 according to the embodiment, the concentration of the p-type impurity in the p⁺-type second collector layer can be increased in order to reduce the ON resistance without increasing the turn-off power loss.

### Second Embodiment

Next, a semiconductor device 200 according to a second embodiment is described using FIG. 2. FIG. 2 is a cross-sectional view of a main part of an IGBT 200 that is a semiconductor device according to the second embodiment. Portions with the same configuration as that described in the first embodiment are marked with the same reference numerals or symbols, and a description thereof is omitted. Differences from the first embodiment are mainly described.

As shown in FIG. 2, the IGBT 200 according to the embodiment differs from the IGBT 100 according to the first embodiment in that the current narrowing body 14 is hollow. Otherwise, both have the same structure. That is, the IGBT 200 according to the embodiment has a structure in which the insulating film of the current narrowing body 11 is replaced with a cavity in the IGBT 100 according to the first embodiment. The current narrowing body formed of such a cavity can be formed by, for example, a method in which a current narrowing body is beforehand formed of a sacrifice layer that is more easily etched than the p⁻-type first collector layer and the p⁺-type second collector layer, and the sacrifice layer is etched through a not-shown via for etching extending from the surface of the p⁺-type second collector layer to the sacrifice layer. The cavity is filled with the atmosphere outside the IGBT 200.

Since the current is concentrated in the space 14A by the current narrowing body 14 formed of such a cavity, also the IGBT 200 according to the embodiment can provide similar effects to the IGBT 100 according to the first embodiment.

Although the current narrowing bodies 11 and 14 are adjacent to the p⁺-type second collector layer in the embodiments described above, a structure may be used in which they are away from the p⁺-type second collector layer 10 via the p⁻-type first collector layer 9. Thereby, the collector resistance can be further reduced to reduce the ON resistance. Furthermore, although the IGBT with a trench-like gate electrode is described, the embodiment can be also applied to IGBTs with a planar gate electrode as a matter of course.

Furthermore, in the IGBTs 100 and 200, the gate electrode 7 and the current narrowing bodies 11 and 14 may be patterned into stripes, a lattice, a houndstooth check (offset lattice), a honeycomb, or the like to the extent that the cross-sectional structures shown in FIG. 1 and FIG. 2 are obtained.

Moreover, although the embodiments are described using the case where the first conduction type is an n-type and the second conduction type is a p-type, a structure in which both types are exchanged may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device comprising:
a first semiconductor layer of a first conduction type;
a second semiconductor layer of the first conduction type provided on the first semiconductor layer and containing a first conduction type impurity in a concentration lower than a first conduction type impurity concentration of the first semiconductor layer;
a third semiconductor layer of a second conduction type formed on a surface of the second semiconductor layer on a side opposite to the first semiconductor layer;
a fourth semiconductor layer of the first conduction type formed on a surface of the third semiconductor layer on a side opposite to the first semiconductor layer and containing a first conduction type impurity in a concentration higher than a first conduction type impurity concentration of the second semiconductor layer;
a gate insulating film provided in contact with the second semiconductor layer, the third semiconductor layer, and the fourth semiconductor layer;
a gate electrode provided opposite the second semiconductor layer, the third semiconductor layer, and the fourth semiconductor layer via the gate insulating film;
an interlayer insulating film provided on the gate electrode and covering the gate electrode along with the gate insulating film;
a fifth semiconductor layer of the second conduction type provided on a surface of the first semiconductor layer on a side opposite to the second semiconductor layer;
a sixth semiconductor layer of the second conduction type provided on a surface of the fifth semiconductor layer on a side opposite to the first semiconductor layer and containing a second conduction type impurity in a concentration higher than a second conduction type impurity concentration of the fifth semiconductor layer;
an insulative current narrowing body provided in the fifth semiconductor layer and having a surface parallel to the surface of the fifth semiconductor layer and a space provided in the surface;
a first electrode electrically connected to the sixth semiconductor layer; and
a second electrode electrically connected to the third semiconductor layer and the fourth semiconductor layer.

2. The device according to claim 1, wherein the space of the current narrowing body is filled with the fifth semiconductor layer and the fifth semiconductor layer is electrically connected to the sixth semiconductor layer via the space.

3. The device according to claim 1, wherein the current narrowing body is adjacent to the sixth semiconductor layer.

4. The device according to claim 1, wherein the current narrowing body is away from the sixth semiconductor layer via the fifth semiconductor layer.

5. The device according to claim 1, wherein the current narrowing body is away from the first semiconductor layer via the fifth semiconductor layer.

6. The device according to claim 1, wherein a net concentration of a second conduction type impurity of the fifth semiconductor layer is higher than a net concentration of a first conduction type impurity of the first semiconductor layer.

7. The device according to claim 1, wherein the current narrowing body is an insulating film.

8. The device according to claim 7, wherein the insulating film is a silicon oxide film or a silicon nitride film.

9. The device according to claim 1, wherein the current narrowing body is hollow.

10. The device according to claim 1, wherein
a trench adjacent to the fourth semiconductor layer, penetrating through the third semiconductor layer from a surface of the fourth semiconductor layer, and reaching an interior of the second semiconductor layer is formed and
the gate electrode is provided in the trench via the gate insulating film.

11. The device according to claim 2, wherein the current narrowing body is adjacent to the sixth semiconductor layer.

12. The device according to claim 3, wherein a net concentration of a second conduction type impurity of the fifth semiconductor layer is higher than a net concentration of a first conduction type impurity of the first semiconductor layer.

13. The device according to claim 6, wherein the current narrowing body is an insulating film.

14. The device according to claim 13, wherein the insulating film is a silicon oxide film or a silicon nitride film.

15. The device according to claim 14, wherein
a trench adjacent to the fourth semiconductor layer, penetrating through the third semiconductor layer from a surface of the fourth semiconductor layer, and reaching an interior of the second semiconductor layer is formed and
the gate electrode is provided in the trench via the gate insulating film.

16. The device according to claim 6, wherein the current narrowing body is hollow.

17. The device according to claim 16, wherein
a trench adjacent to the fourth semiconductor layer, penetrating through the third semiconductor layer from a surface of the fourth semiconductor layer, and reaching an interior of the second semiconductor layer is formed and
the gate electrode is provided in the trench via the gate insulating film.
